(19) United States
(12) Patent Application Publication
(10) Pub. No.: US 2002/0001935 A1
(43) Pub. Date: Jan. 3, 2002

(54) METHOD OF FORMING GATE ELECTRODE IN SEMICONDUCTOR DEVICE

(76) Inventors: HYEON SOO KIM, TAEGU (KR); JIN HONG LEE, KYOUNGKI-DO (KR); IN SEOK YEO, KYOUNGKI-DO (KR)

Correspondence Address: THOMAS F PETERSON, LADAS & PARRY, 224 SOUTH MICHIGAN AVENUE, CHICAGO, IL, 60604

(21) Appl. No.: 09/434,755

(22) Filed: Nov. 5, 1999

(30) Foreign Application Priority Data
Dec. 17, 1998 (KR) 98-55660
Dec. 21, 1998 (KR) 98-56803

(51) Int. Cl. H01L 21/3205; H01L 21/4763

(52) U.S. Cl. 438/595; 438/588

(57) ABSTRACT

A method of forming a gate electrode in semiconductor device which can prevent transformation of the gate electrode, is disclosed. According to the present invention, a gate insulating layer, a doped polysilicon layer and a sacrificial layer are formed on a semiconductor substrate, sequentially. The sacrificial layer and the polysilicon layer are then etched in the shape of a gate electrode to form a sacrificial pattern and a polysilicon pattern. Next, the substrate is re-oxidized to form a re-oxidation layer on the side walls of the polysilicon pattern and LDD ions are implanted into the substrate of both sides of the re-oxidation layer. A spacer of an insulating layer is then formed on the side walls of the sacrificial pattern and the re-oxidation layer and impurity ions of a high concentration are implanted into the substrate of both sides of the spacer. Thereafter, an intermediate insulating layer is formed on the overall substrate and etched to expose the surface of the sacrificial pattern. The exposed sacrificial pattern is then removed to form a trench and a barrier metal layer is formed on the surface of the trench. Next, a refractory metal layer is formed so as to fill the trench on which the barrier metal layer is formed, to form a gate electrode having the polysilicon pattern, the barrier metal layer and the refractory metal. Furthermore, the sacrificial layer is formed to the thickness of 500 to 1,500 Å using a silicon nitride layer. The sacrificial pattern is selectively removed by wet etching using H₃PO₄.

### BACKGROUND OF THE INVENTION

1. Field of the Invention

The present invention relates to a method of manufacturing semiconductor device, and more particularly to a method of forming gate electrode with a stacked structure in which a refractory metal is formed on a polysilicon layer in semiconductor device.

2. Description of the Related Art

Since the resistivity of a gate electrode is important factor in the manufacture of highly integration of semiconductor device, the gate electrode is formed to a stacked structure in which a refractory metal layer such as tungsten(W) layer is formed on a polysilicon layer, for reducing the resistivity of the gate electrode. A barrier metal layer is also formed between the polysilicon layer and the tungsten layer to prevent diffusion therebetween. The barrier metal layer is formed to a titanium nitride(TiN) layer or a tungsten nitride(WN) layer.

A method of forming the gate electrode having the stacked structure according to a conventional art will be explained with reference to FIG. 1.

Referring to FIG. 1, on a semiconductor substrate is formed a gate insulating layer 11, a doped polysilicon layer 12, a barrier metal layer 13 and a W layer 14, sequentially. A hard mask is then formed on the W layer by photolithography and etching process. The hard mask is formed of an insulating layer. It is also used for preventing reflection of metal layer and forming self-aligned contact. The W layer 14, the barrier metal 13 and the polysilicon layer 12 are then etched to form a gate electrode 100.

Thereafter, for removing damage due to the etching process, a re-oxidation process is performed to form a re-oxidation layer 16 on the side walls of the gate electrode 100 and to recover the reliability of the gate insulating layer 11.

In the re-oxidation process, however, the volume of the W layer 14 expands due to its fast oxidation rate, so that a tungsten oxide(WO₃) layer 200 is formed on the side walls of the gate electrode 100, as shown in FIG. 1, thereby transforming the morphology of the gate electrode 100. Therefore, it is difficult to perform ion-implantation for forming a source and a drain and the resistivity of the gate electrode increases, thereby deteriorating reliability of device.

### SUMMARY OF THE INVENTION

It is therefore an object of the present invention to a method of forming a gate electrode in semiconductor device which can prevent transformation of the gate electrode by hindering oxidation of a refractory metal such as a tungsten during re-oxidation process, for solving the problems in the conventional art.

To accomplish this above object, according to a first embodiment of the present invention, a gate insulating layer, a doped polysilicon layer and a sacrificial layer are formed on a semiconductor substrate, sequentially. The sacrificial layer and the polysilicon layer are then etched in the shape of a gate electrode to form a sacrificial pattern and a polysilicon pattern. Next, the substrate is re-oxidized to form a re-oxidation layer on the side walls of the polysilicon pattern. LDD ions are then implanted into the substrate of both sides of the re-oxidation layer. A spacer of an insulating layer is then formed on the side walls of the sacrificial pattern and the re-oxidation layer. Thereafter, impurity ions of a high concentration are implanted into the substrate of both sides of the spacer. An intermediate insulating layer is then formed on the overall substrate and etched to expose the surface of the sacrificial pattern. The exposed sacrificial pattern is then removed to form a trench and a barrier metal layer is formed on the surface of the trench. Next, a refractory metal layer is formed so as to fill the trench on which the barrier metal layer is formed, to form a gate electrode including the polysilicon pattern, the barrier metal layer and the refractory metal.

In the first embodiment, the sacrificial layer is formed to the thickness of 500 to 1,500 Å using a silicon nitride layer. The sacrificial pattern is selectively removed by wet etching using H₃PO₄.

Furthermore, according to a second embodiment, a gate insulating layer and a doped polysilicon layer are formed on a semiconductor substrate, sequentially. The polysilicon layer is then etched in the shape of a gate electrode to form a polysilicon pattern. Next, the substrate is re-oxidized to form a re-oxidation layer on the side walls of the polysilicon pattern. LDD ions are then implanted into the substrate of both sides of the re-oxidation layer and a spacer of an insulating layer is formed on the side walls of the re-oxidation layer. Impurity ions of a high concentration are then implanted into the substrate of both sides of the spacer. Thereafter, an intermediate insulating layer is formed on the overall substrate and etched to expose the polysilicon pattern. The exposed polysilicon pattern is then partially etched to a selected thickness to form a trench and a barrier metal layer is formed on the surface of the trench. Next, a refractory metal layer is formed so as to fill the trench on which the barrier metal layer is formed, to form a gate electrode including the polysilicon pattern, the barrier metal layer and the refractory metal.

In the second embodiment, the polysilicon layer is formed to the thickness of 500 to 3,000 Å and the polysilicon pattern is performed to the thickness of 200 to 1,000 Å by dry etching or wet etching.

Additional object, advantages and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

FIG. 1 is a cross sectional view describing a method of forming a gate electrode in a semiconductor device according to a conventional art.

FIG. 2A to FIG. 2H are cross sectional views describing a method of forming a gate electrode in a semiconductor device according to a first embodiment of the present invention.

FIG. 3A to FIG. 3F are cross sectional views of describing a method of forming a gate electrode in a semiconductor device according to a second embodiment of the present invention.

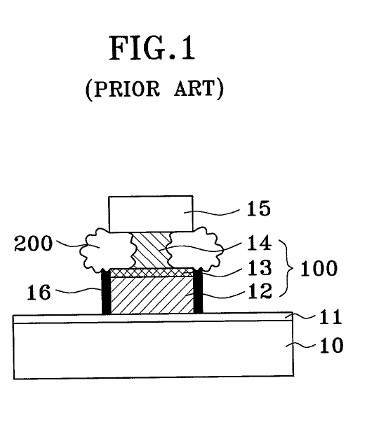

### DETAILED DESCRIPTION OF THE INVENTION

Hereinafter, preferred embodiments of the present invention will be explained with reference to accompanying drawings.

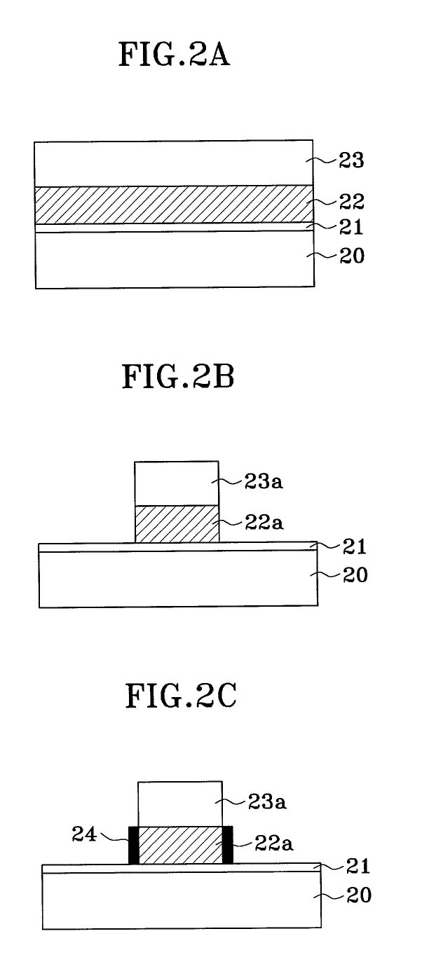

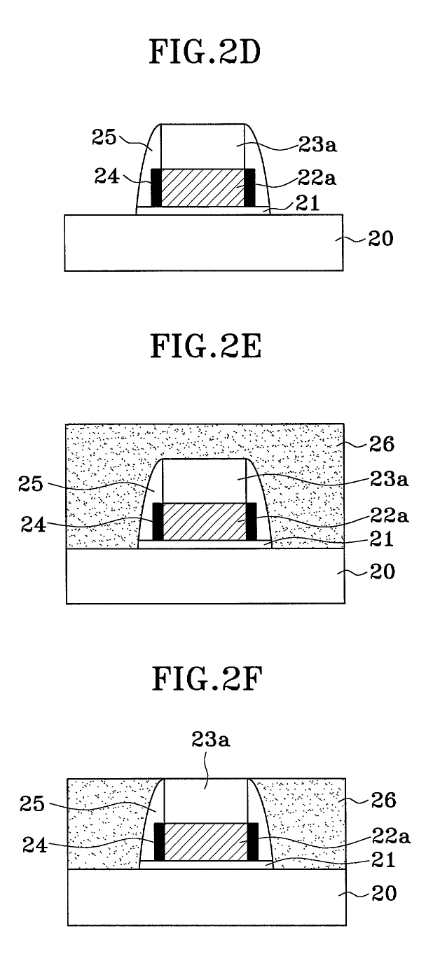

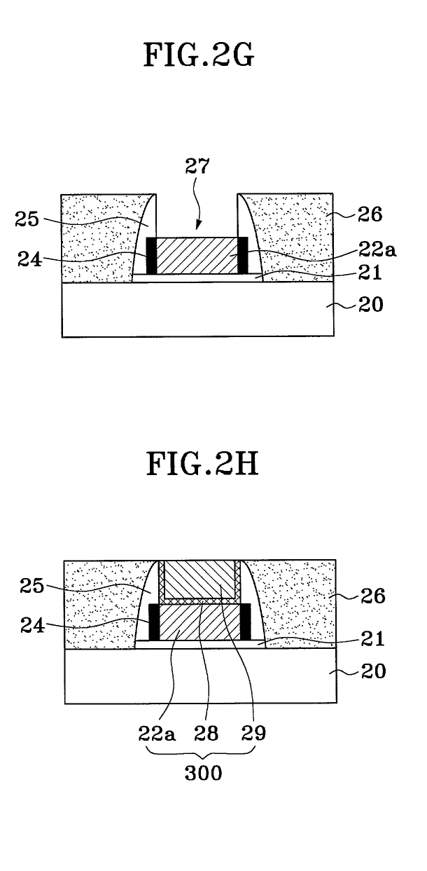

Firstly, a method of forming a gate electrode in a semiconductor device according to a first embodiment of the present invention will be explained with reference to FIG. 2A to FIG. 2H.

Referring to FIG. 2A, a gate insulating layer 21 is formed on a semiconductor substrate 20 by a thermal oxidation process. A doped polysilicon layer 22 is then formed on the gate insulating layer 21 to the thickness of 500 to 1,500 Å and a silicon nitride layer 23 is formed thereon as a sacrificial layer. Preferably, the silicon nitride layer 23 is formed to the thickness of 500 to 1,500 Å.

Referring to FIG. 2B, a photoresist pattern(not shown) for a gate electrode is formed on the silicon nitride layer 23 by photolithography. The silicon nitride layer 23 and the polysilicon layer 22 are then etched by etching process using the photoresist pattern as an etch mask, to form a silicon nitride pattern 23a and a polysilicon pattern 22a. The photoresist pattern is then removed by a well-known method. Thereafter, for removing damage due to the etching process, a re-oxidation process is performed to form a re-oxidation layer 24 on the side walls of the polysilicon pattern 22a and to recover the reliability of the gate insulating layer 21, as shown in FIG. 2C. Preferably, the re-oxidation layer 24 is formed to the thickness of 10 to 300 Å. LDD(Lightly Doped Drain) ions are then implanted into the substrate 20 of both sides of the re-oxidation layer 24 to form LDD regions(not shown).

Referring to FIG. 2D, an insulating layer is deposited on the overall substrate and etched by blanket etching, to form a spacer 25 on the side walls of the silicon nitride pattern 23a and the re-oxidation layer 24. For example, the insulating layer is formed of one selected from an oxide layer, a nitride layer and a staked layer of the oxide layer and the nitride layer. Next, impurity ions of high concentration are implanted into the substrate 20 of both sides of the spacer 25 to form source and drain regions(not shown).

Referring to FIG. 2E, an intermediate insulating layer 26 is formed on the overall substrate. Preferably, the intermediate insulating 26 is formed to the thickness of 3,000 to 5,000 Å by chemical vapor deposition(CVD) using a silicon oxide layer. As shown in FIG. 2F, the intermediate insulating layer 26 is etched by chemical mechanical polishing(CMP) to expose the silicon nitride pattern 23a. Referring to FIG. 2G, the exposed silicon nitride pattern 23a is selectively removed by wet etching using H₃PO₄ to form a trench 27 exposing the polysilicon pattern 22a.

Referring to FIG. 2H, a barrier metal layer 28 is formed on the surface of the trench 27 to the thickness of 10 to 500 Å. Preferably, the barrier metal layer 28 is formed of a tungsten nitride layer or a titanium nitride layer. A tungsten layer 29 as a refractory metal layer is then formed on the overall substrate so as to fill the trench 27 on which the barrier metal layer 28 is formed. Preferably, the tungsten layer 29 is formed to the thickness of 1,000 to 3,000 Å. Next, the tungsten layer 29 is etched by CMP to expose the surface of the intermediate insulating layer 26, thereby forming a gate electrode 300 including the polysilicon pattern 22a, the barrier metal layer 28 and the tungsten layer 29. On the other hand, the tungsten layer 29 may be formed by a selective deposition method, without performing CMP. Furthermore, a silicide layer may be used instead of the refractory metal layer.

According to the first embodiment, by utilizing the sacrificial layer such as the silicon nitride layer, the tungsten layer is formed after performing re-oxidation, so that transformation of the gate electrode occurred by oxidation of the tungsten layer is prevented.

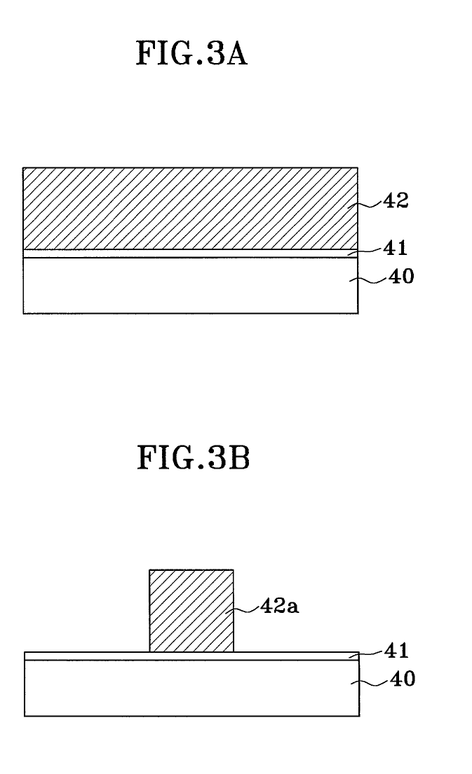

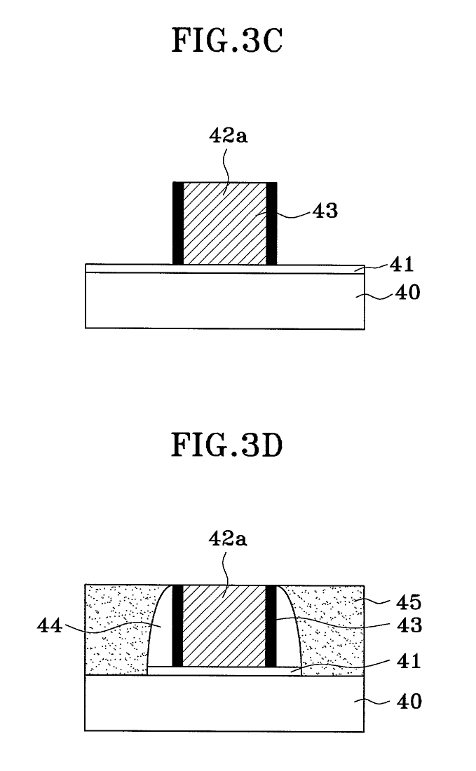

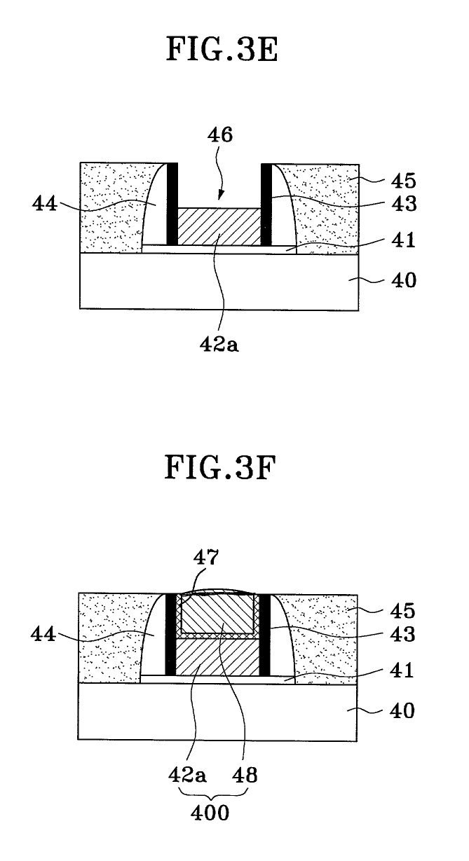

Secondly, a method of forming a gate electrode in a semiconductor device according to a second embodiment of the present invention will be explained with reference to FIG. 3A to FIG. 3F.

Referring to FIG. 3A, a gate insulating layer 41 is formed on a semiconductor substrate 40 and a doped polysilicon layer 42 is formed thereon to the thickness of 500 to 3,000 Å. Referring to FIG. 3B, a photoresist pattern(not shown) is formed on the polysilicon layer 42. The polysilicon layer 42 is then etched by etching process using the photoresist pattern as an etch mask, to form a polysilicon pattern 42a.

Next, the photoresist pattern is removed by a well-known method. For removing damage due to the etching process, a re-oxidation process is then performed to form a re-oxidation layer 43 on the side walls of the polysilicon pattern 42a and to recover the reliability of the gate insulating layer 41, as shown in FIG. 3C. Preferably, the re-oxidation layer 43 is formed to the thickness of 10 to 300 Å. Thereafter, LDD(Lightly Doped Drain) ions are then implanted into the substrate 40 of both sides of the re-oxidation layer 43 to form LDD regions(not shown).

Referring to FIG. 3D, an insulating layer is formed on the overall substrate and etched by blanket etching, to form a spacer 44 on the side walls of the re-oxidation layer 43. For example, the insulating layer is formed of one selected from an oxide layer, nitride layer and a stacked layer of the oxide layer and the nitride layer. Next, impurity ions of high concentration are implanted into the substrate 40 of both sides of the spacer 44 to form source and drain regions(not shown). An intermediate insulating layer 45 is then formed on the overall substrate. Preferably, the intermediate insulating layer 45 is formed to the thickness of 3,000 to 5,000 Å by CVD using a silicon oxide layer. Thereafter, the intermediate insulating 45 is etched by CMP to expose the polysilicon pattern 42a.

Referring to FIG. 3E, the exposed polysilicon pattern 42a is partially etched to a selected thickness, preferably 200 to 1,000 Å by dry etching or wet etching, to form a trench 46.

Referring to FIG. 3F, a barrier metal layer 47 is formed on the surface of the trench 46 to the thickness of 10 to 500 Å.

Preferably, the barrier metal layer 47 is formed of a tungsten nitride layer or titanium nitride layer. A tungsten layer 48 as a refractory metal is then formed on the overall substrate so as to fill the trench 46 on which the barrier metal layer 47 is formed. Preferably, the tungsten layer 48 is formed to the thickness of 1,000 to 3,000 Å. Next, the tungsten layer 48 is etched by CMP to expose the surface of the intermediate insulating layer 45, thereby forming a gate electrode 400 including the polysilicon pattern 42a, the barrier metal layer 47 and the tungsten layer 48. On the other hand, the tungsten layer 48 may be formed by a selective deposition method, without performing CMP. Furthermore, a silicide layer may be used instead of the refractory metal layer.

According to the second embodiment, by partially etching the polysilicon layer without using additional sacrificial layer, the tungsten layer is formed after performing re-oxidation, so that transformation of the gate electrode occurred by oxidation of the tungsten layer is prevented.

According to the present invention, oxidation of a tungsten layer is hindered from re-oxidation process, thereby preventing transformation of the gate electrode. Therefore, it is easy to perform ion-implantation for forming a source and a drain. Furthermore, the resistivity of the gate electrode is reduced, thereby improving reliability of device.

Although the preferred embodiment of this invention has been disclosed for illustrative purpose, those skilled in the art will appreciate that various modifications, additions and substitutions are possible, without departing from the scope and spirit of the invention as described in the accompanying claims.

What is claimed is:

1. A method of forming a gate electrode in semiconductor device, comprising the steps of :
forming a gate insulating layer, a doped polysilicon layer and a sacrificial layer on a semiconductor substrate, sequentially;
etching the sacrificial layer and the polysilicon layer in the shape of a gate electrode to form a sacrificial pattern and a polysilicon pattern;
re-oxidizing the substrate to form a re-oxidation layer on the side walls of the polysilicon pattern;
implanting LDD ions into the substrate of both sides of the re-oxidation layer;
forming a spacer of an insulating layer on the side walls of the sacrificial pattern and the re-oxidation layer;
implanting impurity ions of a high concentration into the substrate of both sides of the spacer;
forming an intermediate insulating layer on the overall substrate;
etching the intermediate insulating layer to expose the surface of the sacrificial pattern;
removing the exposed sacrificial pattern to form a trench;
forming a barrier metal layer on the surface of the trench; and
forming a refractory metal layer so as to fill the trench on which the barrier metal layer is formed, to form a gate electrode having the polysilicon pattern, the barrier metal layer and the refractory metal.

2. The method according to claim 1, wherein the sacrificial layer is formed of a silicon nitride layer.

3. The method according to claim 2, wherein the sacrificial layer is formed to the thickness of 500 to 1,500 Å.

4. The method according to claim 2, wherein the sacrificial pattern is selectively removed by wet etching using H₃PO₄.

5. The method according to claim 1, wherein the polysilicon layer is formed to the thickness of 500 to 1,500 Å.

6. The method according to claim 1, wherein the reoxidation layer is formed to the thickness of 10 to 300 Å.

7. The method according to claim 1, wherein the barrier metal layer is formed of a tungsten nitride layer or a titanium nitride layer.

8. The method according to claim 7, wherein the barrier metal layer is formed to the thickness of 10 to 500 Å.

9. The method according to claim 1, wherein the refractory metal layer is formed of a tungsten layer.

10. The method according to claim 9, wherein the refractory metal layer is formed by depositing the refractory metal on the overall substrate so as to fill the trench on which the barrier metal layer and by etching the refractory metal layer to expose the surface of the intermediate insulating layer.

11. The method according to claim 9, wherein the refractory metal layer is formed by a selected deposition method.

12. A method of forming a gate electrode in semiconductor device, comprising the steps of:
forming a gate insulating layer and a doped polysilicon layer on a semiconductor substrate, sequentially;
etching the polysilicon layer in the shape of a gate electrode to form a polysilicon pattern;
re-oxidizing the substrate to form a re-oxidation layer on the side walls of the polysilicon pattern;
implanting LDD ions into the substrate of both sides of the re-oxidation layer;
forming a spacer of an insulating layer on the side walls of the re-oxidation layer;
implanting impurity ions of a high concentration into the substrate of both sides of the spacer;
forming an intermediate insulating layer on the overall substrate;
etching the intermediate insulating layer to expose the polysilicon pattern;
etching partially the exposed polysilicon pattern to a selected thickness to form a trench;
forming a barrier metal layer on the surface of the trench; and
forming a refractory metal layer so as to fill the trench on which the barrier metal layer is formed, to form a gate electrode having the polysilicon pattern, the barrier metal layer and the refractory metal.

13. The method according to claim 12, wherein the polysilicon layer is formed to the thickness of 500 to 3,000 Å.

14. The method according to claim 13, wherein the etching step of the polysilicon pattern is performed by dry etching or wet etching.

15. The method according to claim 14, wherein the polysilicon pattern is etched to the thickness of 200 to 1,000 Å.

16. The method according to claim 12, wherein the re-oxidation layer is formed to the thickness of 10 to 300 Å.

17. The method according to claim 12, wherein the barrier metal layer is formed of a tungsten nitride layer or a titanium nitride layer.

18. The method according to claim 17, wherein the barrier metal layer is formed to the thickness of 10 to 500 Å.

19. The method according to claim 12, wherein the refractory metal layer is formed of a tungsten layer.

20. The method according to claim 19, wherein the refractory metal is formed by depositing the refractory metal on the overall substrate so as to fill the trench on which the barrier metal layer and by etching the refractory metal layer to expose the surface of the intermediate insulating layer.

21. The method according to claim 19, wherein the refractory metal layer is formed by a selected deposition method.
